(19) United States
(12) Patent Application Publication
(10) Pub. No.: US 2025/0280595 A1
(43) Pub. Date: Sep. 4, 2025

(54) TRANSISTOR AND SEMICONDUCTOR DEVICE USING THE SAME

(71) Applicant: Taiwan Semiconductor Manufacturing Company, Ltd., Hsinchu (TW)

(72) Inventors: I-Sheng CHEN, Hsinchu (TW); Yi-Jing LI, Hsinchu (TW); Shih-Chun FU, Hsinchu (TW); Clement Hsingjen WANN, Carmel, NY (US)

(73) Assignee: Taiwan Semiconductor Manufacturing Company, Ltd., Hsinchu (TW)

(21) Appl. No.: 18/591,873

(22) Filed: Feb. 29, 2024

(51) Int. Cl. H01L 27/06; H01L 23/532; H01L 29/06; H01L 29/775

(52) U.S. Cl. CPC H10D 84/811; H01L 23/53266; H10D 30/43; H10D 62/121

(57) ABSTRACT

A semiconductor device includes a first transistor and a second transistor. The first transistor includes a plurality of first active channels and a first metal gate. The first active channels are stacked to each other. The first metal gate is formed on the first active channels. The first metal gate includes a plurality of first P-metal layers and a first N-metal layer stacked to the first N-metal layer. The second transistor includes a plurality of second active channels and a second metal gate. The second active channels are stacked to each other. The second metal gate is formed on the second active channels, wherein the second metal gate includes a second N-metal layer.

### BACKGROUND

Conventional BJT (bipolar junction transistor) device is commonly used for bandgap reference circuit. However, The BJT occupies a larger area and has a higher power-costing, and thus it is not competitive for shrinkage node.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a first transistor of a semiconductor structure according to an embodiment of the present disclosure;

FIG. 1B illustrates a schematic diagram of a second transistor of the semiconductor structure according to an embodiment of the present disclosure;

FIG. 1C illustrates a schematic diagram of a second transistor of the semiconductor structure according to another embodiment of the present disclosure;

FIG. 1D illustrates a schematic diagram of a first transistor of the semiconductor structure 100 according to another embodiment of the present disclosure;

FIG. 2A illustrates a schematic diagram of a first circuit of the semiconductor structure in an embodiment of the present disclosure;

FIG. 2B illustrates a schematic diagram of a second circuit of the semiconductor structure in another embodiment of the present disclosure;

FIG. 2C illustrates a schematic diagram of a third circuit of the semiconductor structure in another embodiment of the present disclosure;

FIG. 2D illustrates a schematic diagram of a fourth circuit of the semiconductor structure in another embodiment of the present disclosure;

FIG. 2E illustrates a schematic diagram of a fifth circuit of the semiconductor structure in another embodiment of the present disclosure;

FIG. 2F illustrates a schematic diagram of a sixth circuit of the semiconductor structure in another embodiment of the present disclosure;

FIG. 2G illustrates a schematic diagram of a seventh circuit of the semiconductor structure in another embodiment of the present disclosure;

FIG. 3 illustrates a schematic diagram of the current mirror circuit of the semiconductor structure in FIG. 2A.

FIG. 4 illustrates a relationship between the temperature and the reference voltage in an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

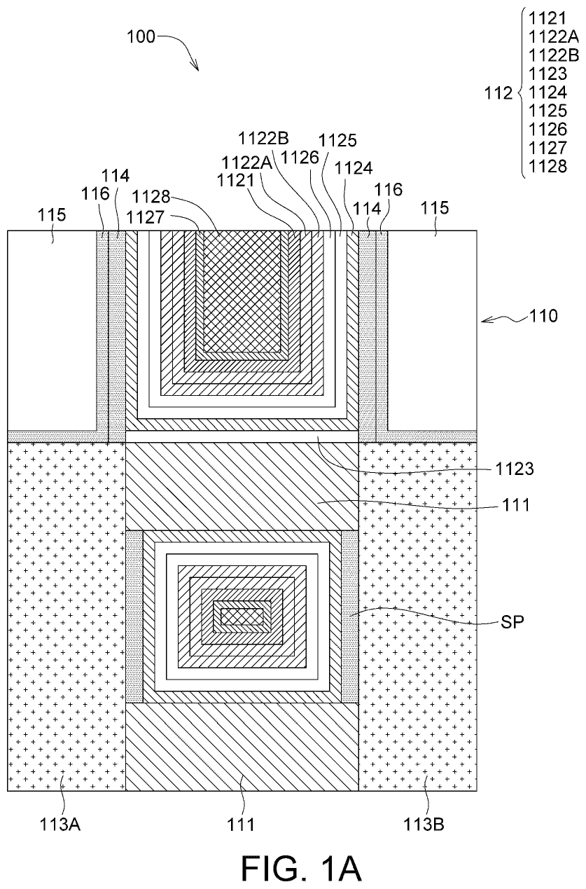

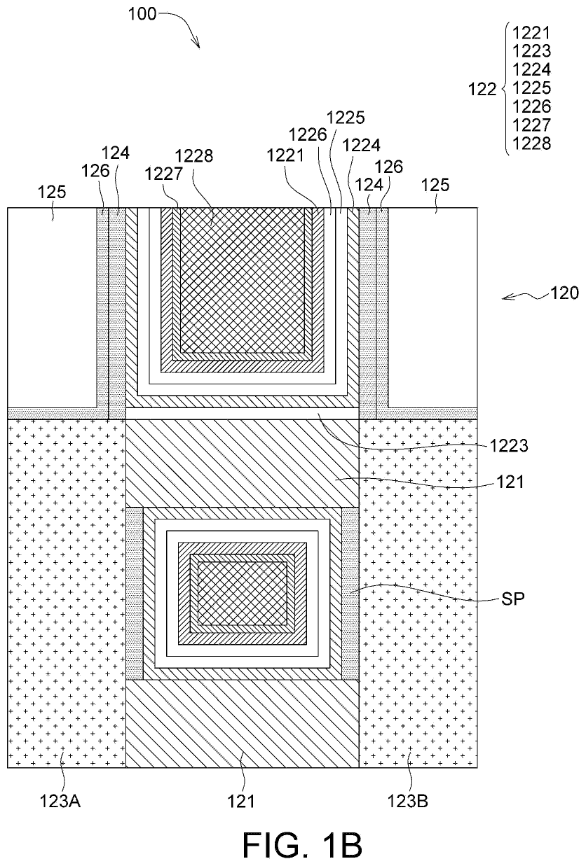

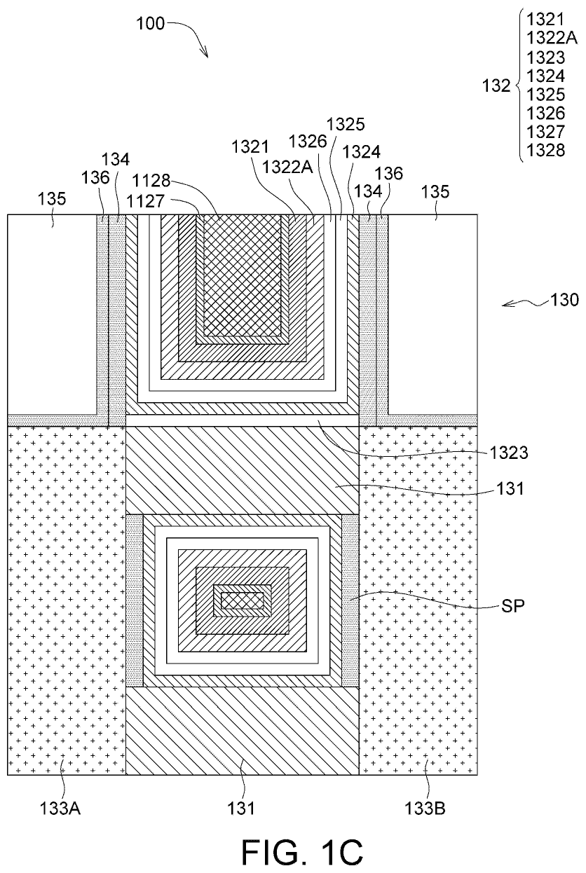

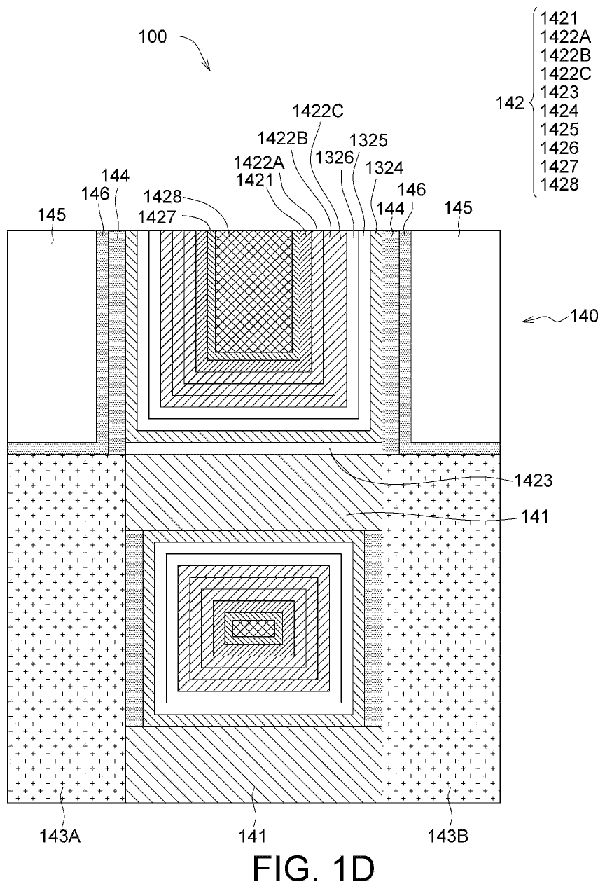

As illustrated in FIGS. 1A to 1D, FIG. 1A illustrates a schematic diagram of a first transistor 110 of a semiconductor structure 100 according to an embodiment of the present disclosure, FIG. 1B illustrates a schematic diagram of a second transistor 120 of the semiconductor structure 100 according to an embodiment of the present disclosure, FIG. 1C illustrates a schematic diagram of a second transistor 130 of the semiconductor structure 100 according to another embodiment of the present disclosure, and FIG. 1D illustrates a schematic diagram of a first transistor 140 of the semiconductor structure 100 according to another embodiment of the present disclosure.

As illustrated in FIGS. 1A to 1D, the semiconductor structure 100 includes a plurality of transistors, for example, at least one first transistor 110, at least one second transistor 120, at least one second transistor 130 and at least one first transistor 140. Although not illustrated, the semiconductor structure 100 further includes a substrate, for example, a portion of silicon wafer. The transistors are formed on the substrate.

As illustrated in FIG. 1A, the first transistor 110 is, for example, a flip-gate NMOS (or called “FGD”). The first transistor 110 includes a plurality of first active channels 111 stacked to each other, a first metal gate 112, a first epitaxy 113A, a second epitaxy 113B, a spacer 114, an interlayer dielectric (ILD) layer 115, a contact etch stop layer (CESL) 116 and at least one inner spacer SP.

As illustrated in FIG. 1A, the first active channel 111 is, for example, silicon sheet (for example, nano-sheet). The first epitaxy 113A may be one of a source and a drain of the first transistor 110, and the second epitaxy 113B may be another of the source and the drain of the first transistor 110. The spacer 114 is formed on a lateral surface of the CESL 116. The CESL 116 surrounds the ILD layer 115. The spacer 114, the ILD layer 115 and the CESL 116 are formed above the first epitaxy 113A and the second epitaxy 113B. The inner spacer SP is formed on a lateral surface of a portion of the first metal gate 112 which is located between the first active channel 111.

As illustrated in FIG. 1A, the first metal gate 112 is formed on and/or between the first active channels 111. The first metal gate 112 includes a first N-metal layer 1121, a plurality of first P-metal layers 1122A and 1122B, an interaction layer (IL) 1123, a high-k layer 1124, a capping layer 1125, a barrier layer 1126, a glue layer 1127 and a metal layer 1128.

As illustrated in FIG. 1A, the interaction layer 1123, the high-k layer 1124, the capping layer 1125, the barrier layer 1126, the first P-metal layer 1122B, the first P-metal layer 1122A, the first N-metal layer 1121, the glue layer 1127 and the metal layer 1128 are formed, in order, in a manufacturing process of the transistor.

In an embodiment, the first N-metal layer 1121 may be formed of a material including TAL material. The first P-metal layer 1122A and the first P-metal layer 1122B may be formed a material including, for example, TiN, etc. The interaction layer 1123 may be formed a material including, for example, TaN, etc. The high-k layer 1124 may be formed of a material including: (i) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (Al), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9). The capping layer 1125 may be formed a material including, for example, TiN, etc. The barrier layer 1126 may be formed a material including, for example, TaN, etc. The glue layer 1127 may be formed a material including, for example, TiN, etc. The metal layer 1128 may be formed a material including, for example, tungsten, etc.

In addition, the P-metal layer has a work-function different from that of the N-metal layer, and one of the P-metal layers may have the work-function different from or the same as another of the P-metal layers.

As illustrated in FIG. 1B, the second transistor 120 is, for example, a negative-gate device NMOS (or called “NGD”). The second transistor 120 includes a plurality of second active channels 121 stacked to each other, a second metal gate 122, a first epitaxy 123A, a second epitaxy 123B, a spacer 124, an ILD layer 125 and a CESL 126 and at least one inner spacer SP.

As illustrated in FIG. 1B, the second active channel 121 is, for example, silicon sheet (for example, nano-sheet). The first epitaxy 123A may be one of a source and a drain of the second transistor 120, and the second epitaxy 123B may be another of the source and the drain of the second transistor 120. The spacer 124 is formed on a lateral surface of the CESL 126. The CESL 126 surrounds the ILD layer 125. The spacer 124, the ILD layer 125 and the CESL 126 are formed above the first epitaxy 123A and the second epitaxy 123B. The inner spacer SP is formed on a lateral surface of a portion of the second metal gate 122 which is located between the second active channel 121.

As illustrated in FIG. 1B, the second metal gate 122 is formed on and between the second active channels 121. The second metal gate 122 includes a second N-metal layer 1221, an interaction layer 1223, a high-k layer 1224, a capping layer 1225, a barrier layer 1226, a glue layer 1227 and a metal layer 1228. Difference from the first metal gate 112 is that the second metal gate 122 may omit the first P-metal layer. As a result, a second driving voltage threshold Vₜ₂ for the second metal gate 122 (or the second transistor 120) is less than a first driving voltage threshold Vₜ₁ for the first metal gate 112 (or the first transistor 110). In an embodiment, the second driving voltage threshold Vₜ₂ for the second metal gate 122 (or the second transistor 120) is, for example, 0.38 volts, and the first driving voltage threshold Vₜ₁ for the first metal gate 112 (or the first transistor 110) is, for example, 0.72 volts. The driving voltage threshold is the voltage which may successfully drive the transistor to work.

As illustrated in FIG. 1B, the interaction layer 1223, the high-k layer 1224, the capping layer 1225, the barrier layer 1226, the second N-metal layer 1221, the glue layer 1227 and the metal layer 1228 are formed, in order, in a manufacturing process of the transistor.

In an embodiment, the second N-metal layer 1221 may be formed of a material the same as or similar to that of the first N-metal layer 1121. The interaction layer 1223 may be formed a material the same as or similar to that of the interaction layer 1123. The high-k layer 1224 may be formed of a material the same as or similar to that of the high-k layer 1124. The capping layer 1225 may be formed a material the same as or similar to that of the capping layer 1125. The barrier layer 1226 may be formed a material the same as or similar to that of the barrier layer 1126. The glue layer 1227 may be formed a material the same as or similar to that of the glue layer 1127. The metal layer 1228 may be formed a material the same as or similar to that the metal layer 1128.

As illustrated in FIG. 1C, the second transistor 130 is, for example, a negative-gate device NMOS (or called “NGD”). The second transistor 130 includes a plurality of second active channels 131 stacked to each other, a second metal gate 132, a first epitaxy 133A, a second epitaxy 133B, a spacer 134, an ILD layer 135 and a CESL 136.

As illustrated in FIG. 1C, the second active channel 131 is, for example, silicon sheet (for example, nano-sheet). The first epitaxy 13A may be one of a source and a drain of the second transistor 130, and the second epitaxy 133B may be another of the source and the drain of the second transistor 130. The spacer 134 is formed on a lateral surface of the CESL 136. The CESL 136 surrounds the ILD layer 135. The spacer 134, the ILD layer 135 and the CESL 136 are formed above the first epitaxy 133A and the second epitaxy 133B. The inner spacer SP is formed on a lateral surface of a portion of the first metal gate 132 which is located between the first active channel 131.

As illustrated in FIG. 1C, the second metal gate 132 is formed on and between the second active channels 131. The second metal gate 132 includes a second N-metal layer 1321, a second P-metal layer 1322A, an interaction layer 1323, a high-k layer 1324, a capping layer 1325, a barrier layer 1326, a glue layer 1327 and a metal layer 1328. Difference from the second metal gate 122 is that the number of the second P-metal layer of the second metal gate 132 is greater than the number of the second P-metal layer of the second metal gate 122. As a result, a second driving voltage threshold Vₜ₂ for the second metal gate 132 (or the second transistor 130) is greater than the second driving voltage threshold Vₜ₂ for the second metal gate 122 (or the second transistor 120). Similarly, the number of the second P-metal layer of the second metal gate 132 is less than the number of the first P-metal layer of the first metal gate 112. As a result, the second driving voltage threshold Vₜ₂ for the second metal gate 132 (or the second transistor 130) is less than the first driving voltage threshold Vₜ₁ for the first metal gate 112 (or the first transistor 110). In an embodiment, the second driving voltage threshold for the second metal gate 132 (or the second transistor 130) is, for example, 0.54 volts.

As illustrated in FIG. 1C, the interaction layer 1323, the high-k layer 1324, the capping layer 1325, the barrier layer 1326, the second P-metal layer 1322A, the second N-metal layer 1321, the glue layer 1327 and the metal layer 1328 are formed, in order, in a manufacturing process of the transistor.

In an embodiment, the second N-metal layer 1321 may be formed of a material the same as or similar to that of the first N-metal layer 1121. The second P-metal layer 1322A may be formed of a material the same as or similar to that of the first P-metal layer 1122A. The interaction layer 1323 may be formed a material the same as or similar to that of the interaction layer 1123. The high-k layer 1324 may be formed of a material the same as or similar to that of the high-k layer 1124. The capping layer 1325 may be formed a material the same as or similar to that of the capping layer 1125. The barrier layer 1326 may be formed a material the same as or similar to that of the barrier layer 1126. The glue layer 1327 may be formed a material the same as or similar to that of the glue layer 1127. The metal layer 1328 may be formed a material the same as or similar to that the metal layer 1128.

As illustrated in FIG. 1D, the first transistor 140 is, for example, a flip-gate NMOS (or called “FGD”). The first transistor 140 includes a plurality of first active channels 141 stacked to each other, a first metal gate 142, a first epitaxy 143A, a second epitaxy 143B, a spacer 144, an (ILD layer 145 and a CESL 146.

As illustrated in FIG. 1D, the first active channel 141 is, for example, silicon sheet (for example, nano-sheet). The first epitaxy 143A may be one of a source and a drain of the first transistor 140, and the second epitaxy 143B may be another of the source and the drain of the first transistor 140. The spacer 144 is formed on a lateral surface of the CESL 146. The CESL 146 surrounds the ILD layer 145. The spacer 144, the ILD layer 145 and the CESL 146 are formed above the first epitaxy 143A and the second epitaxy 143B. The inner spacer SP is formed on a lateral surface of a portion of the first metal gate 142 which is located between the first active channel 141.

As illustrated in FIG. 1D, the first metal gate 142 is formed on and between the first active channels 141. The first metal gate 142 includes a first N-metal layer 1421, a plurality of first P-metal layers 1422A, 1422B and 1422C, an interaction layer 1423, a high-k layer 1424, a capping layer 1425, a barrier layer 1426, a glue layer 1427 and a metal layer 1428. Difference from the second metal gate 122 is that the number of the first P-metal layer of the first metal gate 142 is greater than the number of the second P-metal layer of the second metal gate 122. As a result, a first driving voltage threshold Vₜ₁ for the first metal gate 142 (or the first transistor 140) is greater than the second driving voltage threshold Vₜ₂ for the second metal gate 122 (or the second transistor 120). In an embodiment, the first driving voltage threshold Vₜ₁ for the first metal gate 142 is, for example, 0.844 volts.

In another embodiment, the number of the P-metal layers may be greater than 3.

As described above, the driving voltage threshold of the metal gate increases with the increasing of the number of the P-metal layers.

As illustrated in FIG. 1D, the interaction layer 1423, the high-k layer 1424, the capping layer 1425, the barrier layer 1426, the first P-metal layer 1422C, the first P-metal layer 1422B, the first P-metal layer 1422A, the first N-metal layer 1421, the glue layer 1427 and the metal layer 1428 are formed, in order, in a manufacturing process of the transistor.

In an embodiment, the first N-metal layer 1421 may be formed of a material the same as or similar to that of the first N-metal layer 1121. The first P-metal layer 1422A may be formed of a material the same as or similar to that of the first P-metal layer 1122A. The first P-metal layer 1422B may be formed of a material the same as or similar to that of the first P-metal layer 1122B. The first P-metal layer 1422C may be formed of a material including, for example, TiN, etc. The interaction layer 1423 may be formed a material the same as or similar to that of the interaction layer 1123. The high-k layer 1424 may be formed of a material the same as or similar to that of the high-k layer 1124. The capping layer 1425 may be formed a material the same as or similar to that of the capping layer 1125. The barrier layer 1426 may be formed a material the same as or similar to that of the barrier layer 1126. The glue layer 1427 may be formed a material the same as or similar to that of the glue layer 1127. The metal layer 1428 may be formed a material the same as or similar to that the metal layer 1128.

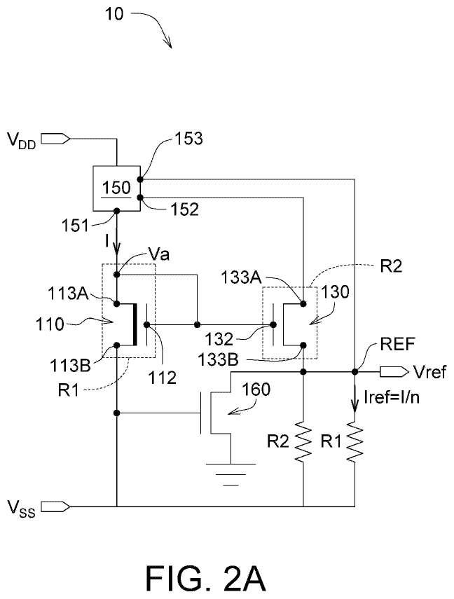

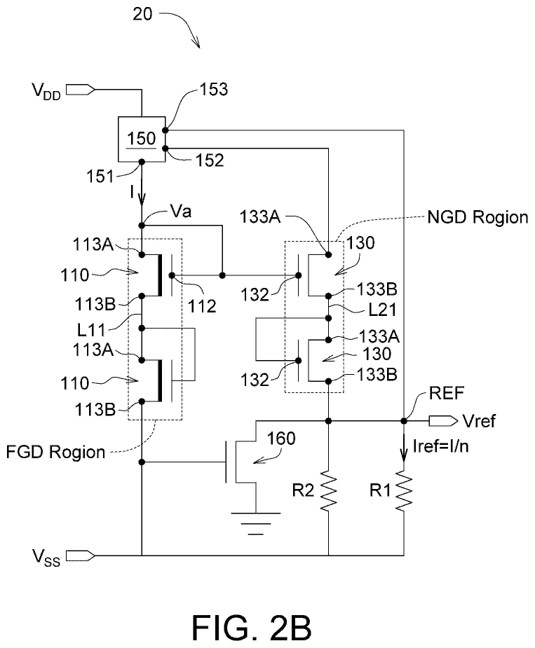

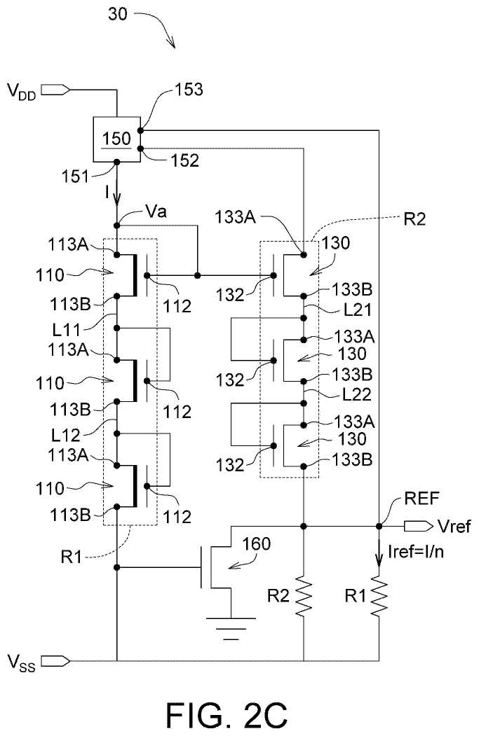

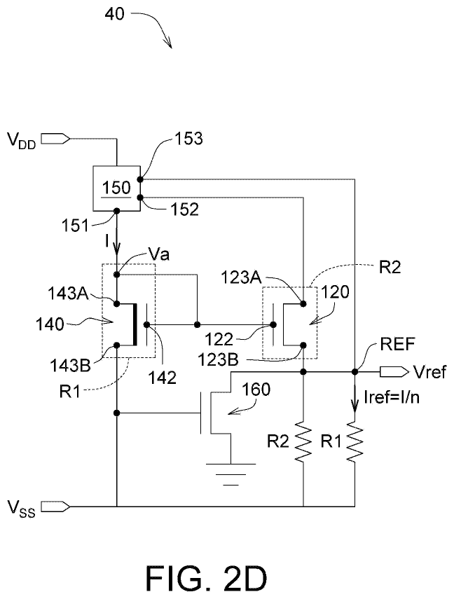

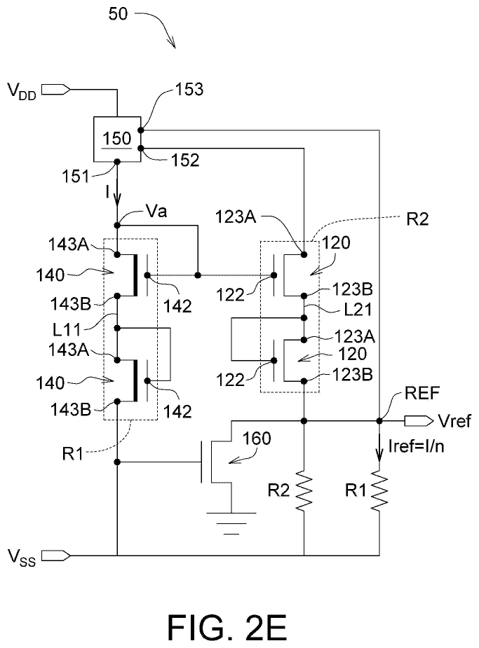

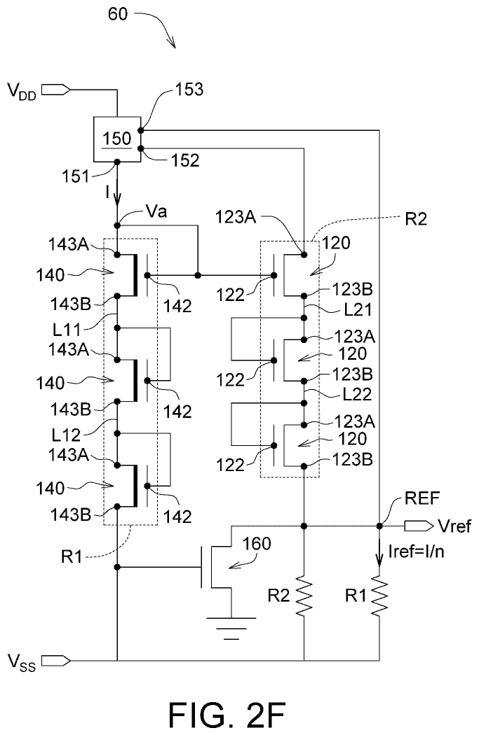

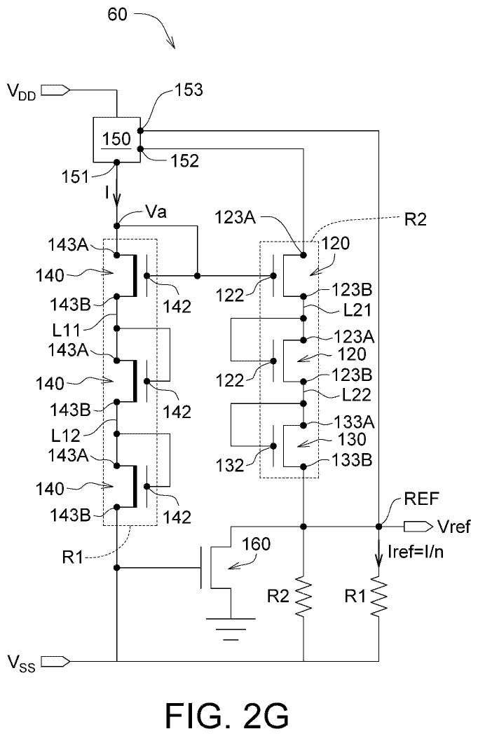

As illustrated in FIGS. 2A to 2G, FIG. 2A illustrates a schematic diagram of a first circuit 10 of the semiconductor structure 100 in an embodiment of the present disclosure, FIG. 2B illustrates a schematic diagram of a second circuit 20 of the semiconductor structure 100 in another embodiment of the present disclosure, FIG. 2C illustrates a schematic diagram of a third circuit 30 of the semiconductor structure 100 in another embodiment of the present disclosure, FIG. 2D illustrates a schematic diagram of a fourth circuit 40 of the semiconductor structure 100 in another embodiment of the present disclosure, FIG. 2E illustrates a schematic diagram of a fifth circuit 50 of the semiconductor structure 100 in another embodiment of the present disclosure, FIG. 2F illustrates a schematic diagram of a sixth circuit 60 of the semiconductor structure 100 in another embodiment of the present disclosure, and FIG. 2G illustrates a schematic diagram of a seventh circuit 70 of the semiconductor structure 100 in another embodiment of the present disclosure.

As illustrated in FIG. 2A, the first transistor 110 is located at a first region A1, and the second transistor 130 is located at a second region A2. In an embodiment, all transistors in the first region A1 are FGD, while all transistors in the second region A2 are NGD. In another embodiment, all transistors in the first region A1 may be a combination of the FGD and the NGD, and/or all transistors in the second region A2 may be a combination of the FGD and the NGD.

As illustrated in FIG. 2A, the first epitaxy 113A may be the source of the first transistor 110, and the second epitaxy 113B may be the drain of the first transistor 110. The first epitaxy 133A may be the source of the second transistor 130, and the second epitaxy 133B may be the drain of the second transistor 130. The first metal gate 112 of the first transistor 110 is electrically connected with the second metal gate 132 of the second transistor 130, and the first epitaxy 113A of the first transistor 110 is electrically connected with a first node 151 of a current mirror circuit 150. The current mirror circuit 150 may supply a driving current (or subthreshold current of the FGD) I to the first transistor 110. The first epitaxy 133A of the second transistor 130 is electrically connected with a second node 152 of the current mirror circuit 150. The current mirror circuit 150 electrically connects a device voltage V_{DD} with the first epitaxy 113A of the first transistor 110. The current mirror circuit 150 is configured to convert the device voltage V_{DD} to a node voltage Va.

As illustrated in FIG. 2A, a first resistor R1 electrically connects a third node 153 of the current mirror circuit 150 with a series voltage V_{SS}, and a second resistor R2 electrically connects the second epitaxy 133B of the second transistor 130 with the series voltage V_{SS}. A reference node REF between the current mirror circuit 150 and the first resistor R1 has a reference voltage V_{ref}. In an embodiment, the first resistor R1 has a resistance greater than that of the second resistor R2, and thus it may amplify the reference voltage V_{ref}. The reference voltage V_{ref} is proportional to a difference between the first driving voltage threshold Vₜ₁ and the second driving voltage threshold Vₜ₂.

As illustrated in FIG. 2A, the semiconductor structure 100 further includes a fifth transistor 160. The fifth transistor 160 electrically connects a line between the second epitaxy 133B of the second transistor 130 and the second resistor R2 with the second epitaxy 113B of the first transistor 110. The fifth transistor 160 is configured to conduct a leakage current to a grounding.

In an embodiment, as shown in Table 1, in case of the first region A1 including one first transistor 110 and the second region A2 including one second transistor 130, the reference voltage V_{ref} is about 0.2V±0.02 V. In case of the first region A1 including one first transistor 140 and the second region A2 including one second transistor 130, the reference voltage V_{ref} is about 0.3V±0.02 V. In case of the first region A1 including one first transistor 110 and the second region A2 including one second transistor 120, the reference voltage V_{ref} is about 0.35V±0.02 V. In case of the first region A1 including one first transistor 140 and the second region A2 including one second transistor 120 (that is, the circuit in FIG. 2D), the reference voltage V_{ref} is about 0.5V±0.02 V. Furthermore, due to the semiconductor structure 100 including the FGD transistor (for example, the first transistor 110 and/or the first transistor 140), and it may increase the reference voltage V_{ref}. In addition, the more the number of the P-type metals of the FGD transistor in the first region A1 is, the greater the reference voltage V_{ref} is.

TABLE 1

| | first region A1 | |
|---|---|---|
| | first transistor 110 | first transistor 140 |
| second region A2 | (FGD) | (FGD) |
| second transistor 130 (NGD) | 0.2 V ± 0.02 V | 0.3 V ± 0.02 V |
| second transistor 120 (NGD) | 0.35 V ± 0.02 V | 0.5 V ± 0.02 V |

As illustrated in FIG. 2B, two first transistors 110 connected with each other are located at the first region A1, and two second transistors 130 connected with each other are located at the second region A2. The first metal gate 112 of one of the two first transistors 110 is electrically connected with a line L11 between the two first transistors 110. The second metal gate 132 of one of the two second transistors 130 is electrically connected with a line L21 between the two second transistors 130.

As illustrated in FIG. 2B, the first epitaxy 113A may be the source of the first transistor 110, and the second epitaxy 113B may be the drain of the first transistor 110. The first epitaxy 113A of the first transistor 110 is electrically connected with the first node 151 of the current mirror circuit 150. The current mirror circuit 150 may supply the driving current I to the first transistor 110. The first metal gate 112 of a first one (the upper one) of the first transistors 110 is electrically connected with the second metal gate 132 of a first one (the upper one) of the second transistors 130, the first epitaxy 113A of a second one (the lower one) of the first transistors 110 is electrically connected with the second epitaxy 113B of the first one of the first transistors 110, and the second epitaxy 113B of the second one of the first transistors 110 is electrically connected with the series voltage V_{SS}.

As illustrated in FIG. 2B, the first epitaxy 133A may be the source of the second transistor 130, and the second epitaxy 133B may be the drain of the second transistor 130. The first epitaxy 133A of a first one (the upper one) the second transistors 130 is electrically connected with the second node 152 of the current mirror circuit 150. The first epitaxy 133A of a second one (the lower one) of the second transistors 130 is electrically connected with the second epitaxy 133B of the first one (the upper one) of the second transistors 130, and the second epitaxy 133B of the second one of the second transistors 130 is electrically connected with the second resistor R2.

As illustrated in FIG. 2B, the first resistor R1 electrically connects the third node 153 of the current mirror circuit 150 with the series voltage V_{SS}, and the second resistor R2 electrically connects the second epitaxy 133B of the second one of the second transistors 130 with the series voltage V_{SS}. The reference node REF between the current mirror circuit 150 and the first resistor R1 has the reference voltage V_{ref}. In an embodiment, the first resistor R1 has the resistance greater than that of the second resistor R2, and thus it may amplify the reference voltage V_{ref}. The fifth transistor 160 electrically connects a line between the second epitaxy 133B of the second one of the second transistors 130 and the second resistor R2 with the second epitaxy 113B of the second one of the first transistors 110. The fifth transistor 160 may conduct the leakage current to the grounding.

In another embodiment, the second transistors 130 in FIG. 2B may be replaced by the second transistors 120 and/or the first transistors 110 in FIG. 2B may be replaced by the first transistors 140.

As illustrated in FIG. 2C, three first transistors 110 connected with each other are located at the first region A1, and three second transistors 130 connected with each other are located at the second region A2. The first metal gate 112 of a first one (the middle one) of the three first transistors 110 is electrically connected with a first line L11 between the first one and a second one (the upper one) of the three first transistors 110. The first metal gate 112 of a third one (the lower one) of the three first transistors 110 is electrically connected with a second line L2 between the first one and the third one. The second metal gate 132 of a first one (the middle one) of the three second transistors 130 is electrically connected with a first line L21 between the first one and a second one (the upper one) of the three second transistors 130, the second metal gate 132 of a third one (the lower one) of the three second transistors 130 is electrically connected with a second line L22 between the first one and the third one of the three second transistors 130.

As illustrated in FIG. 2C, the first epitaxy 113A may be the source of the first transistor 110, and the second epitaxy 113B may be the drain of the first transistor 110. The first epitaxy 113A of the second one (the upper one) of the first transistors 110 is electrically connected with the first node 151 of the current mirror circuit 150. The current mirror circuit 150 may supply the driving current I to the first transistor 110. The first metal gate 112 of the second one (the upper one) of the first transistors 110 is electrically connected with the second metal gate 132 of the second one (the upper one) of the second transistors 130, the first epitaxy 113A of the first one (the middle one) of the first transistors 110 is electrically connected with the second epitaxy 113B of the second one (the upper one) of the first transistors 110, and the second epitaxy 113B of the first one (the middle one) of the first transistors 110 is electrically connected with the first epitaxy 113A of the third one (the lower one) of the first transistors 110. The second epitaxy 113B of the third one of the first transistors 110 is electrically connected with the series voltage V_{SS}.

As illustrated in FIG. 2C, the second epitaxy 133A may be the source of the second transistor 130, and the second epitaxy 133B may be the drain of the second transistor 130. The first epitaxy 133A of the second one (the upper one) of the second transistors 130 is electrically connected with the second node 152 of the current mirror circuit 150. The second metal gate 132 of the second one (the upper one) of the second transistors 130 is electrically connected with the first metal gate 112 of the second one (the upper one) of the first d transistors 110, the first epitaxy 133A of the first one (the middle one) of the second transistors 130 is electrically connected with the second epitaxy 133B of the second one (the upper one) of the second transistors 130, and the second epitaxy 133B of the first one (the middle one) of the second transistors 130 is electrically connected with the first epitaxy 133A of the third one (the lower one) of the second transistors 130, and the second epitaxy 133B of the third one (the lower one) of the second transistors 130 is electrically connected with the second resistor R2.

As illustrated in FIG. 2C, the first resistor R1 electrically connects the third node 153 of the current mirror circuit 150 with the series voltage V_{SS}, and the second resistor R2 electrically connects the second epitaxy 133B of the third one (the lower one) of the second transistors 130 with the series voltage V_{SS}. The reference node REF between the third node 153 of the current mirror circuit 150 and the first resistor R1 has the reference voltage V_{ref}. In an embodiment, the first resistor R1 has the resistance greater than that of the second resistor R2, and thus it may amplify the reference voltage V_{ref}. The fifth transistor 160 electrically connects a line between the second epitaxy 133B of the third one (the lower one) of the second transistors 130 and the second resistor R2 with the second epitaxy 113B of the third one (the lower one) of the first transistors 110. The fifth transistor 160 may conduct the leakage current to the grounding.

As shown in Table 2 below, the more the number of the FD transistors is, the greater the reference voltage V_{ref} is, the less the range (a difference of the maximum reference voltage and the minimum reference voltage is, and the less the standard deviation of the reference voltages V_{ref} is. In addition, as long as the reference voltage V_{ref} in Table 2 may be obtained, the embodiment of the present disclosure does not limit the value of the first resistor R1, the value of the current I, the value of the second resistor R2, the value of the first driving voltage threshold Vₜ₁, the value of the second driving voltage threshold Vₜ₂ and/or the value of other relevant parameter.

TABLE 2

| | standard |
|---|---|
| range | deviation |

| | |
|---|---|
| reference voltage V_{ref} | Monte-carlo 1000 cycles |

| | | | | |
|---|---|---|---|---|
| Circuit 10 | 0.2 | V | ±2.5% | <1% |
| Circuit 20 | 0.35 | V | ±1.5% | <0.5% |
| Circuit 30 | 0.5 | V | ±1.1% | <0.5% |

As illustrated in FIG. 2D, the first transistor 140 is located at the first region A1, and the second transistor 120 is located at the second region A2. The first epitaxy 143A may be the source of the first transistor 140, and the second epitaxy 143B may be the drain of the first transistor 140. The first epitaxy 123A may be the source of the second transistor 120, and the second epitaxy 123B may be the drain of the second transistor 120. The first metal gate 142 of the first transistor 140 is electrically connected with the second metal gate 122 of the second transistor 120, and the first epitaxy 143A of the first transistor 140 is electrically connected with the first node 151 of the current mirror circuit 150. The current mirror circuit 150 may supply the driving current I to the first transistor 140. The first epitaxy 123A of the second transistor 120 is electrically connected with the second node 152 of the current mirror circuit 150. The current mirror circuit 150 electrically connects the device voltage V_{DD} with the first epitaxy 143A of the first transistor 110. The current mirror circuit 150 is configured to convert the device voltage V_{DD} to the node voltage Va.

As illustrated in FIG. 2D, the first resistor R1 electrically connects the third node 153 of the current mirror circuit 150 with the series voltage V_{SS}, and the second resistor R2 electrically connects the second epitaxy 123B of the second transistor 120 with the series voltage V_{SS}. The reference node REF between the current mirror circuit 150 and the first resistor R1 has the reference voltage V_{ref}. In an embodiment, the first resistor R1 has the resistance greater than that of the second resistor R2, and thus it may amplify the reference voltage V_{ref}.

As illustrated in FIG. 2D, the fifth transistor 160 electrically connects the line between the second epitaxy 123B of the second transistor 120 and the second resistor R2 with the second epitaxy 143B of the first transistor 140. The fifth transistor 160 is configured to conduct a leakage current to the grounding.

As illustrated in FIG. 2E, two first transistors 140 connected with each other are located at the first region A1, and two second transistors 120 connected with each other are located at the second region A2. The first metal gate 142 of one of the two first transistors 140 is electrically connected with the line L11 between the two first transistors 140. The second metal gate 122 of one of the two second transistors 120 is electrically connected with the line L21 between the two second transistors 120.

As illustrated in FIG. 2E, the first epitaxy 143A may be the source of the first transistor 140, and the second epitaxy 143B may be the drain of the first transistor 140. The first epitaxy 143A of the first transistor 140 is electrically connected with the first node 151 of the current mirror circuit 150. The current mirror circuit 150 may supply the driving current I to the first transistor 140. The first metal gate 142 of a first one (the upper one) of the first transistors 140 is electrically connected with the second metal gate 122 of the first one (the upper one) of the second transistors 120, the first epitaxy 143A of the second one (the lower one) of the first transistors 140 is electrically connected with the second epitaxy 143B of the first one (the upper one) of the first transistors 140, and the second epitaxy 143B of the second one (the lower one) of the first transistors 140 is electrically connected with the series voltage V_{SS}.

As illustrated in FIG. 2E, the first epitaxy 123A may be the source of the second transistor 120, and the second epitaxy 123B may be the drain of the second transistor 120. The first epitaxy 123A of a first one (the upper one) of the second transistor 120 is electrically connected with the second node 152 of the current mirror circuit 150. The first epitaxy 123A of the second one (the lower one) of the second transistors 120 is electrically connected with the second epitaxy 123B of the first one (the upper one) of the second transistors 120, and the second epitaxy 123B of the second one (the lower one) of the second transistors 120 is electrically connected with the second resistor R2.

As illustrated in FIG. 2E, the first resistor R1 electrically connects the third node 153 of the current mirror circuit 150 with the series voltage V_{SS}, and the second resistor R2 electrically connects the second epitaxy 123B of the second one of the second transistors 120 with the series voltage V_{SS}. The reference node REF between the current mirror circuit 150 and the first resistor R1 has the reference voltage V_{ref}. In an embodiment, the first resistor R1 has the resistance greater than that of the second resistor R2, and thus it may amplify the reference voltage V_{ref}. The fifth transistor 160 electrically connects the line between the second epitaxy 123B of the second one (the lower one) of the second transistors 120 and the second resistor R2 with the second epitaxy 143B of the second one (the lower one) of the first transistors 140. The fifth transistor 160 may conduct the leakage current to the grounding.

As illustrated in FIG. 2F, three first transistors 140 connected with each other are located at the first region A1, and three second transistors 120 connected with each other are located at the second region A2. The first metal gate 142 of the first one (the middle one) of the three first transistors 140 is electrically connected with the first line L11 between the first one and a second one (the upper one) of the three first transistors 140. The first metal gate 142 of the third one (the lower one) of the three first transistors 140 is electrically connected with the second line L12 between the first one and the third one. The second metal gate 122 of the first one (the middle one) of the three second transistors 120 is electrically connected with the first line L21 between the first one and the second one (the upper one) of the three second transistors 120, the second metal gate 122 of the third one (the lower one) of the three second transistors 120 is electrically connected with the second line L22 between the first one and the third one of the three second transistors 120.

As illustrated in FIG. 2F, the first epitaxy 143A may be the source of the first transistor 140, and the second epitaxy 143B may be the drain of the first transistor 140. The first epitaxy 143A of the second one (the upper one) of the first transistors 140 is electrically connected with the first node 151 of the current mirror circuit 150. The current mirror circuit 150 may supply the driving current I to the first transistor 140. The first metal gate 142 of the second one (the upper one) of the first transistors 140 is electrically connected with the second metal gate 122 of the second one (the upper one) of the second transistors 120, the first epitaxy 143A of the first one (the middle one) of the first transistors 140 is electrically connected with the second epitaxy 143B of the second one (the upper one) of the first transistors 140, and the second epitaxy 143B of the first one (the middle one) of the first transistors 140 is electrically connected with the first epitaxy 143A of the third one (the lower one) of the first transistors 140. The second epitaxy 143B of the third one of the first transistors 140 is electrically connected with the series voltage V_{SS}.

As illustrated in FIG. 2F, the second epitaxy 123A may be the source of the second transistor 120, and the second epitaxy 123B may be the drain of the second transistor 120. The first epitaxy 123A of the second one (the upper one) of the second transistors 120 is electrically connected with the second node 152 of the current mirror circuit 150. The second metal gate 122 of the second one (the upper one) of the second transistors 120 is electrically connected with the first metal gate 142 of the second one (the upper one) of the first transistors 140, the first epitaxy 123A of the first one (the middle one) of the second transistors 120 is electrically connected with the second epitaxy 123B of the second one (the upper one) of the second transistors 120, and the second epitaxy 123B of the first one (the middle one) of the second transistors 120 is electrically connected with the first epitaxy 123A of the third one (the lower one) of the second transistors 120, and the second epitaxy 123B of the third one (the lower one) of the second transistors 120 is electrically connected with the second resistor R2.

As illustrated in FIG. 2F, the first resistor R1 electrically connects the third node 153 of the current mirror circuit 150 with the series voltage V_{SS}, and the second resistor R2 electrically connects the second epitaxy 123B of the third one (the lower one) of the second transistors 120 with the series voltage V_{SS}. The reference node REF between the third node 153 of the current mirror circuit 150 and the first resistor R1 has the reference voltage V_{ref}. In an embodiment, the first resistor R1 has the resistance greater than that of the second resistor R2, and thus it may amplify the reference voltage V_{ref}. The fifth transistor 160 electrically connects the line between the second epitaxy 123B of the third one (the lower one) of the second transistors 120 and the second resistor R2 with the second epitaxy 143B of the third one (the lower one) of the first transistors 140. The fifth transistor 160 may conduct the leakage current to the grounding.

As illustrated in FIG. 2G, the seventh circuit 70 includes the features similar to that of the sixth circuit 60, and the difference is that a combination of at least one second transistor 120 and at least one second transistor 130 are disposed in the second region A2. In another embodiment, a combination of at least one first transistor 110 and at least one first transistor 140 are disposed in the first region A1 of the seventh circuit 70.

As shown in Table 3 below, the more the number of the FGD transistors is, the greater the reference voltage V_{ref} is, the less the range (the difference of the maximum reference voltage and the minimum reference voltage is, and the less the standard deviation of the reference voltages V_{ref} is. In addition, as long as the reference voltage V_{ref} in Table 3 may be obtained, the embodiment of the present disclosure does not limit the value of the first resistor R1, the value of the current I, the value of the second resistor R2, the value of the first driving voltage threshold Vₜ₁, the value of the second driving voltage threshold Vₜ₂ and/or the value of other relevant parameter.

TABLE 3

| | standard |
|---|---|
| range | deviation |

| | |
|---|---|
| reference voltage V_{ref} | Monte-carlo 1000 cycles |

| | | | | |
|---|---|---|---|---|
| Circuit 40 | 0.5 | V | ±2.5% | <1% |
| Circuit 50 | 1 | V | ±1.5% | <0.5% |
| Circuit 60 | 1.4 | V | ±1.1% | <0.5% |
| Circuit 70 | 1.2 | V | ±1.1% | <0.5% |

As described above, in an embodiment, the first region A1 may include at least one FGD transistor (for example, the first transistor 110 and/or the first transistor 140), and the second region A2 may include at least one NGD transistor (for example, the second transistor 120 and/or the second transistor 130). In another embodiment, the first region A1 may include a combination of at least one FGD transistor (for example, the first transistor 110 and/or the first transistor 140) and at least one NGD transistor (for example, the second transistor 120 and/or the second transistor 130), and/or the second region A2 may include a combination of at least one FGD transistor (for example, the first transistor 110 and/or the first transistor 140) and at least one NGD transistor (for example, the second transistor 120 and/or the second transistor 130).

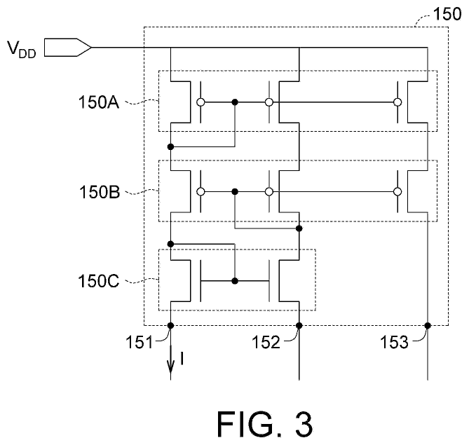

As illustrated in FIG. 3, FIG. 3 illustrates a schematic diagram of the current mirror circuit 150 of the semiconductor structure 100 in FIG. 2A. The current mirror circuit 150 includes a PMOS upper current mirror 150A, a PMOS lower current mirror 150B and a NMOS current mirror 150C which are electrically connected with each other. Through a circuit design of the PMOS upper current mirror 150A, the PMOS lower current mirror 150B and the NMOS current mirror 150C, the current mirror circuit 150 may supply the driving current I to the first transistor (for example, the first transistors 110 and 140).

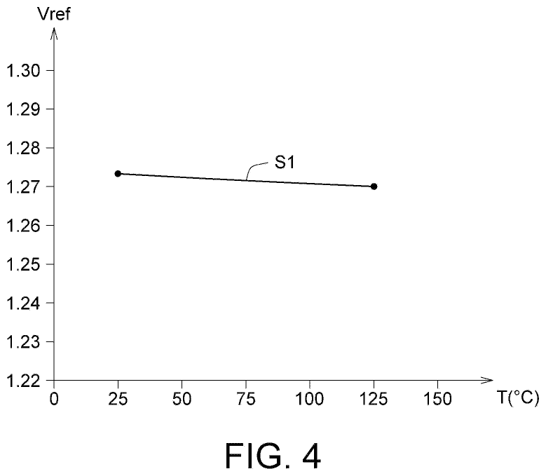

As illustrated in FIG. 4, FIG. 4 illustrates a relationship SI between the temperature and the reference voltage V_{ref} in an embodiment of the present disclosure. As illustrated in FIGS. 2A to 2G, the reference current I_{ref} (or subthreshold current of NGD) of the reference node REF is equal to I/n.

The reference voltage V_{ref} may be obtained by the formula (1) below, wherein Vₜ₁ is the first driving voltage threshold, Vₜ₂ is the second driving voltage threshold, T is temperature, and q is magnitude of the electrical charge on the electron, k is Boltzmann constant, and γ is sub-threshold swing coefficient. The sub-threshold swing coefficient γ depends on the gate oxide capacitance and/or the depletion layer capacitance of the source/drain junction of the semiconductor device 100.

$${V}_{ref} = ( {V}_{t 1} - {V}_{t 2} ) + γ \times ln ( n ) \times \frac{kT}{q} \qquad ( 1 )$$

The differentiation of the reference voltage V_{ref} over temperature (namely, ∂V_{ref}/∂T) may be obtained by the formula (2) below. When n is equal to 1, ∂V_{ref}/∂T is equal to 0, and it means that the reference voltage V_{ref} does not change with temperature. The suitable or expected value of n may be obtained through adjusting the value of n in a simulation process or a testing process, and then the current mirror circuit 150 and/or other related circuits may be design according to the obtained value of n for making the reference voltage V_{ref} remain constant over temperature, or making the change of the reference voltage V_{ref} over temperature be less than a default value, as illustrated in FIG. 4. In an embodiment, the value of n may range between 0.01 and 100.

$$\frac{\partial {V}_{ref}}{\partial T} = \frac{\partial ( {V}_{t 1} - {V}_{t 2} )}{\partial T} + γ \times \frac{kT}{q} \times ln ( n ) \qquad ( 2 )$$

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes at least one FGD transistor and at least one NGD transistor connected with the FGD transistor. In comparison with the conventional semiconductor device (for example, BJT) which does not include the FGD transistor, the reference voltage range of the semiconductor device may meet general specification ±3% or greater. In addition, in comparison with the conventional semiconductor device which does not include the FGD transistor, the power saving for the semiconductor device is about 80%, and the area reduction for the semiconductor device is about 70%.

Example embodiment 1: a transistor includes a plurality of active channels and a metal gate. The active channels are stacked to each other. The metal gate is formed on the active channels, wherein the metal gate includes a plurality of P-metal layers and a N-metal layer stacked on the P-metal layers.

Example embodiment 2 based on Example embodiment 1: each of the P-metal layers is formed of TiN.

Example embodiment 3 based on Example embodiment 1: the metal gate further includes an interaction layer, a high-k layer, a capping layer and a barrier layer. The high-k layer is stacked on the interaction layer. The capping layer is stacked on the high-k layer. The barrier layer is stacked on the capping layer. The P-metal layers are stacked on the barrier layer.

Example embodiment 4 based on Example embodiment 3: the capping layer is formed of TiN.

Example embodiment 5 based on Example embodiment 3: the barrier layer is formed of TaN.

Example embodiment 6 based on Example embodiment 1: the metal gate further includes a metal layer and a glue layer. The glue layer is formed between the metal layer and the N-metal layer.

Example embodiment 7 based on Example embodiment 1: the number of the P-metal layers is equal to or greater than 3.

Example embodiment 8: a semiconductor device includes a first transistor and a second transistor. The first transistor includes a plurality of first active channels and a first metal gate. The first active channels are stacked to each other. The first metal gate is formed on the first active channels. The first metal gate includes a plurality of first P-metal layers and a first N-metal layer stacked to the first P-metal layers. The second transistor includes a plurality of second active channels and a second metal gate. The second active channels are stacked to each other. The second metal gate is formed on the second active channels, wherein the second metal gate includes a second N-metal layer.

Example embodiment 9 based on Example embodiment 8: the first transistor has a first driving voltage threshold, and the second transistor has a second driving voltage threshold less than the first driving voltage threshold.

Example embodiment 10 based on Example embodiment 8: the first metal gate of the first transistor is electrically connected with the second metal gate of the second transistor.

Example embodiment 11 based on Example embodiment 8: the number of the first P-metal layers is two or three.

Example embodiment 12 based on Example embodiment 8: the semiconductor device further includes two first transistors connected with each other and two second transistors connected with each other, and the first metal gate of one of the two first transistors is electrically connected with the second metal gate of one of the two second transistors.

Example embodiment 13 based on Example embodiment 8: the second metal gate further includes a second P-metal layer stacked to the second N-metal layer.

Example embodiment 14 based on Example embodiment 13: the semiconductor device further includes two first transistors connected with each other and two second transistors connected with each other, and the first metal gate of one of the two first transistors is electrically connected with the second metal gate of one of the two second transistors.

Example embodiment 15 based on Example embodiment 8: the semiconductor device further includes three first transistors connected with each other and three second transistors connected with each other, and the first metal gate of one of three first transistors is electrically connected with the second metal gate of one of the three second transistors.

Example embodiment 16 based on Example embodiment 8: the second metal gate further includes a second P-metal layer stacked to the second N-metal layer. The semiconductor device further includes three first transistors connected with each other and three second transistors connected with each other, and the first metal gate of one of three first transistors is electrically connected with the second metal gate of one of the three second transistors.

Example embodiment 17 based on Example embodiment 8: the semiconductor device further includes a current mirror circuit, a first resistor and a second resistor. The current mirror circuit is electrically connected with the first transistor. The first resistor electrically connects the current mirror circuit with a series voltage. The second resistor electrically connects the second transistor with the series voltage.

Example embodiment 18: a semiconductor device includes a first transistor and a plurality of second transistors. The first transistor includes a plurality of first active channels and a first metal gate. The first active channels are stacked to each other. The first metal gate is formed on the first active channels. The first metal gate includes a plurality of first P-metal layers and a first N-metal layer stacked to the first P-metal layers. Each second transistor includes a plurality of second active channels and a second metal gate. The second active channels are stacked to each other. The second metal gate is formed on the second active channels, wherein the second metal gate includes a second N-metal layer. Wherein one of the second transistors further includes a second P-metal layer, and is electrically connected with another of the second transistors.

Example embodiment 19 based on Example embodiment 18: the first transistor has a first driving voltage threshold, and each second transistor has a second driving voltage threshold less than the first driving voltage threshold.

Example embodiment 20 based on Example embodiment 18: the semiconductor device further includes two first transistors connected with each other, and the first metal gate of one of the two first transistors is electrically connected with the second metal gate of one of the two second transistors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor, comprising:
a plurality of active channels stacked to each other; and
a metal gate formed on the active channels, wherein the metal gate comprises:
a plurality of P-metal layers; and
a N-metal layer stacked on the P-metal layers.

2. The transistor as claimed in claim 1, wherein each of the P-metal layers is formed of TiN.

3. The transistor as claimed in claim 1, wherein the metal gate further comprises:
an interaction layer;
a high-k layer stacked on the interaction layer;
a capping layer stacked on the high-k layer; and
a barrier layer stacked on the capping layer;
wherein the P-metal layers are stacked on the barrier layer.

4. The transistor as claimed in claim 3, wherein the capping layer is formed of TiN.

5. The transistor as claimed in claim 3, wherein the barrier layer is formed of TaN.

6. The transistor as claimed in claim 1, wherein the metal gate further comprises:
a metal layer; and
a glue layer formed between the metal layer and the N-metal layer.

7. The transistor as claimed in claim 1, wherein the number of the P-metal layers is equal to or greater than 3.

8. A semiconductor device, comprising:
a first transistor, comprising:
a plurality of first active channels stacked to each other; and
a first metal gate formed on the first active channels, wherein the first metal gate comprises:
a plurality of first P-metal layers; and
a first N-metal layer stacked to the first P-metal layers;
a second transistor, comprising:
a plurality of second active channels stacked to each other; and
a second metal gate formed on the second active channels, wherein the second metal gate comprises a second N-metal layer.

9. The semiconductor device as claimed in claim 8, wherein the first transistor has a first driving voltage threshold, and the second transistor has a second driving voltage threshold less than the first driving voltage threshold.

10. The semiconductor device as claimed in claim 8, wherein the first metal gate of the first transistor is electrically connected with the second metal gate of the second transistor.

11. The semiconductor device as claimed in claim 8, wherein the number of the first P-metal layers is two or three.

12. The semiconductor device as claimed in claim 8, further comprising two first transistors connected with each other and two second transistors connected with each other, and the first metal gate of one of the two first transistors is electrically connected with the second metal gate of one of the two second transistors.

13. The semiconductor device as claimed in claim 8, wherein the second metal gate further comprises a second P-metal layer stacked to the second N-metal layer.

14. The semiconductor device as claimed in claim 13, further comprising two first transistors connected with each other and two second transistors connected with each other, and the first metal gate of one of the two first transistors is electrically connected with the second metal gate of one of the two second transistors.

15. The semiconductor device as claimed in claim 8, further comprising three first transistors connected with each other and three second transistors connected with each other, and the first metal gate of one of three first transistors is electrically connected with the second metal gate of one of the three second transistors.

16. The semiconductor device as claimed in claim 8, wherein the second metal gate further comprises a second P-metal layer stacked to the second N-metal layer;
wherein the semiconductor device further comprises three first transistors connected with each other and three second transistors connected with each other, and the first metal gate of one of three first transistors is electrically connected with the second metal gate of one of the three second transistors.

17. The semiconductor device as claimed in claim 8, further comprises:
a current mirror circuit electrically connected with the first transistor;
a first resistor electrically connecting the current mirror circuit with a series voltage; and
a second resistor electrically connecting the second transistor with the series voltage.

18. A semiconductor device, comprising:
a first transistor, comprising:
a plurality of first active channels stacked to each other; and
a first metal gate formed on the first active channels, wherein the first metal gate comprises:
a plurality of first P-metal layers; and
a first N-metal layer stacked to the first P-metal layers;
a plurality of second transistors, each comprising:
a plurality of second active channels stacked to each other; and
a second metal gate formed on the second active channels, wherein the second metal gate comprises a second N-metal layer;
wherein one of the second transistors further comprises a second P-metal layer, and is electrically connected with another of the second transistors.

19. The semiconductor device as claimed in claim 18, wherein the first transistor has a first driving voltage threshold, and each second transistor has a second driving voltage threshold less than the first driving voltage threshold.

20. The semiconductor device as claimed in claim 18, further comprising two first transistors connected with each other, and the first metal gate of one of the two first transistors is electrically connected with the second metal gate of one of the two second transistors.
